(19) United States
(12) Patent Application Publication
(10) Pub. No.: US 2025/0124542 A1
(43) Pub. Date: Apr. 17, 2025

(54) COMPUTER-IMPLEMENTED METHOD FOR DOWNSCALING OCEAN SURFACE WIND

(71) Applicant: The Hong Kong University of Science and Technology, Hong Kong (CN)

(72) Inventors: Hui SU, Hong Kong (CN); Enze ZHANG, Hong Kong (CN)

(21) Appl. No.: 18/911,679

(22) Filed: Oct. 10, 2024

Related U.S. Application Data
(60) Provisional application No. 63/589,986, filed on Oct. 12, 2023.

(51) Int. Cl. G06T 3/4046; G01P 5/00; G01S 13/95; G06F 30/27; G06T 3/4007; G06T 11/20

(52) U.S. Cl. CPC G06T 3/4046; G01P 5/001; G01S 13/95; G06F 30/27; G06T 3/4007; G06T 11/206

(57) ABSTRACT

A computer-implemented method for downscaling an ocean surface wind (OSW). The method comprises: obtaining an input image with a set of wind data, constructing an OSW downscaling model based on a TransUNet architecture; using the OSW downscaling model to generate an output image with a set of resulting wind data according to the input image, and before the OSW downscaling model is used to generate the output image, training the OSW downscaling model according to a plurality of sets of training samples, wherein the OSW downscaling model is trained by optimizing model parameters of the OSW downscaling model in a sense of minimizing a loss function for improving resolution.

### CROSS-REFERENCE TO RELATED APPLICATIONS

This application claims the benefit of U.S. Provisional Patent Application Ser. No. 63/589,986 filed Oct. 12, 2023, the disclosure of which is incorporated by reference herein in its entirety.

### TECHNICAL FIELD

The present application relates to the field of atmospheric science, in particular, to a computer-implemented method for downscaling an ocean surface wind (OSW).

### BACKGROUND

The current OSW products cannot provide a reliable and accurate wind field under high-speed wind (>15 m/s) conditions. For instance, the Cross-Calibrated Multi-Platform (CCMP) largely underestimated wind speed when the wind speed exceeded 15 m/s during the Typhoon Mangkhut in 2018, compared with the best track datasets (JTWC, CMA, HKO, and TOKYO), as shown in FIG. 1. Another drawback of current OSW products is low spatial resolution. These disadvantages limit its applications in various fields, such as the estimation of wind energy volume, the deployment of offshore wind power stations, and the operation of weather forecasts.

The current limitations are primarily due to the sounding capacity of the instruments boarded on satellites in extreme weather conditions. The CCMP incorporates OSW measurements from the microwave radiometers and scatterometers, whose performance is adversely affected by the raining weather. That's why there are nearly no observations near the center of the typhoon, as shown in FIG. 1. Simultaneously, current OSW products did not include synthetic aperture radar (SAR) and CYGNSS OSW data, which have outstanding performance in rainy weather. The major problem of current OSW products (e.g., CCMP) is poor performance under extreme weather conditions, particularly when the wind speed excesses over 15 m/s. Another disadvantage is the low spatial resolution (˜25 km).

### SUMMARY

The present disclosure provides a computer-implemented method for downscaling an OSW comprising:
obtaining an input image of a set of wind data,
constructing an OSW downscaling model based on a TransUNet architecture,
using the OSW downscaling model to generate an output image of a set of resulting wind data with increased resolution according to the input image, and
before the OSW downscaling model is used to generate the output image, training the OSW downscaling model according to a plurality of sets of training samples, wherein the OSW downscaling model is trained by optimizing model parameters of the OSW downscaling model in a sense of minimizing a loss function.

In certain embodiments, the plurality of sets of training samples comprise a first set of wind data samples and a second set of wind data samples, the first set of wind data samples comprises at least a set of SAR OSW data, and the second set of wind data samples comprises at least a set of CCMP OSW data.

In certain embodiments, typhoon eyes in both the first set and second set of wind data samples are centered within their image frame respectively, so as to reconcile discrepancies caused by time lag between the first set and the second set of wind data samples.

In certain embodiments, if one pixel of a wind image in the first set of wind data sample is less than a first threshold and if a predefined proportion of the surrounding pixels surpass a second threshold, the one pixel is determined to be the typhoon eye in the wind image of the first set of wind data samples.

In certain embodiments, if one pixel of a wind image in the second set of wind data samples is less than a first threshold and if a predefined proportion of the surrounding pixels surpass a second threshold, the one pixel is determined to be the typhoon eye in the wind image of the second set of wind data samples.

In certain embodiments, the training of the OSW downscaling model comprises pairing the wind images of the first set of wind data samples with the wind images of the second set of wind data samples based on the date, when the wind images of the first set of wind data samples and the wind images of the second set of wind data samples are obtained.

In certain embodiments, all data of the paired wind images of the first set of wind data samples and the paired wind images of the second set of wind data samples are separated into training set of data, validation set of data, and test set of data, and the training set of data is configured for updating the model parameters of the OSW downscaling model in a sense of minimizing a loss function.

In certain embodiments, the validation set of data is configured for mitigating overfitting, and the test set of data is configured to estimate the final uncertainty of the OSW downscaling model. In certain embodiments, the first set of wind data samples and the second set of wind data samples in the training set of data are respectively enriched through data augmentation before being input into the OSW downscaling model.

In certain embodiments, the second set of wind data samples have been further upsampled using bilinear interpolation before being input into the OSW downscaling model.

In certain embodiments, all ReLU activation functions are replaced by leaky ReLU activation functions in the OSW downscaling model.

In certain embodiments, the loss function is determined by applying a first mask to the resulting wind data samples obtained by using the OSW downscaling model to calculate a first mean squared error (MSE) value between the first set of wind data samples in the training set of data and the resulting wind data in the regions where wind data in the first set of wind data samples is present, applying a second mask to both the resulting wind data samples obtained by using the OSW downscaling model and the second set of wind data samples in the training set of data to calculate a second MSE value between the second set of wind data samples and the resulting wind data samples obtained by using the OSW downscaling model in regions where the first set of wind data samples is lacking, and combining the first MSE values and the second MSE values.

In certain embodiments, the loss function used for training is expressed as follows:

$$Loss = \frac{1}{{n}_{1}} \times {\sum }_{i}^{N} {( {W}_{SAR}^{i} - {W}_{DL}^{i} )}^{2} \times {mask}^{i} + \frac{1}{{n}_{2}} \times {\sum }_{i}^{N} ( {W}_{CCMP}^{i} - {W}_{DL}^{i} ) \times ( 1 - {mask}^{i} ) \times 0.1$$

where n₁ is the number of pixels that have SAR wind, n₂ is the number of pixels that do not have SAR wind, N is the total number of pixels in the image frame, i represents i^{th} pixel, W_{SAR}ⁱ is i^{th} SAR wind data, W_{CCMP}ⁱ is i^{th} CCMP wind data, W_{DL}ⁱ is i^{th} resulting wind data obtained from the TransUNet architecture, maskⁱ is one if the SAR wind data is available at the i^{th} pixel; otherwise, maskⁱ is zero.

In certain embodiments, the step of training the OSW downscaling model is halted when a validation loss obtained from the loss function does not improve for predetermined consecutive epochs.

The method obtained by the present disclosure achieves high accuracy and high resolution, has a better performance under the high-speed wind condition.

### BRIEF DESCRIPTION OF THE DRAWINGS

Exemplary embodiments of the disclosure are described in the following with respect to the attached figures. The figures and corresponding detailed description serve merely to provide a better understanding of the disclosure and do not constitute a limitation whatsoever of the scope of the disclosure as defined in the claims. In particular:

FIG. 1 illustrates Wind field retrieved from CCMP during the Typhoon Mangkhut in 2018, wherein, (a) shows the wind field at 12:00 UT on Sep. 15, 2018, (b) shows the number of observations used in CCMP wind data process at 12:00 UT on Sep. 15, 2018, and (c) shows the wind maximum near the typhoon center from different data sources, including Joint Typhoon Warning Center (JTWC), Chian Meteorological Administration (CMA), Hong Kong Observatory (HKO), and Japan Meteorological Agency (TOKYO).

FIG. 2 shows a flow diagram of a training method for the OSW downscaling model and an inference method for the OSW downscaling model according to one embodiment of the present disclosure.

FIG. 3 shows a diagram of the TransUNet architecture according to one embodiment of the present disclosure.

FIG. 4 illustrates the comparison between the CCMP wind field (left column), the wind field generated by OSW downscaling model trained by the method of the present disclosure (middle column), and the SAR wind field (right column).

FIG. 5 illustrates the comparison of the total wind speed profile (gray dashed line in FIG. 4) between CCMP wind speed, SAR wind speed, and the wind speed generated by OSW downscaling model trained by the method of the present disclosure.

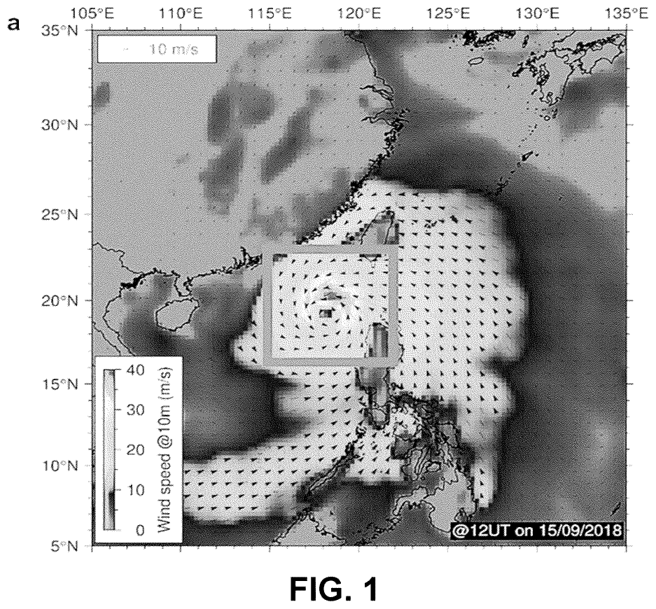

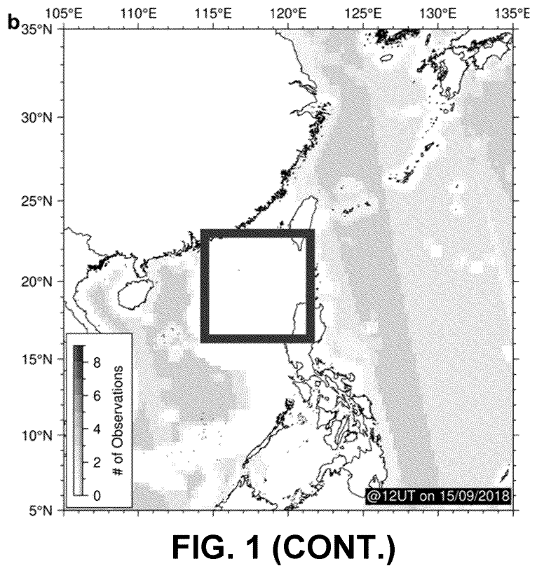

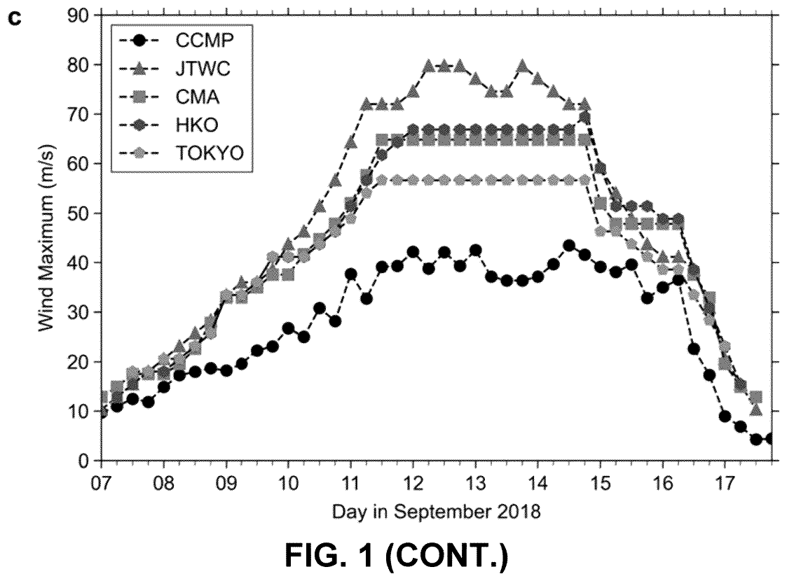

### DETAILED DESCRIPTION

The disclosure will be more fully described below with reference to the accompanying drawings. However, the present disclosure may be embodied in a number of different forms and should not be construed as being limited to the embodiments described herein.

The present disclosure intends to provide a methodology to integrate OSW from different observations using advanced AI technology and increase the resolution of OSW with improved accuracy.

A principal use of the present disclosure is to provide accurate OSW data so as to make a good preparation for the deployment of offshore wind turbines. Another potential use of the present disclosure is to provide accurate weather forecast to government departments and logisitics companies for hazard contingency. For the public, the accurate weather information can help them make more efficient plans for outdoor activities.

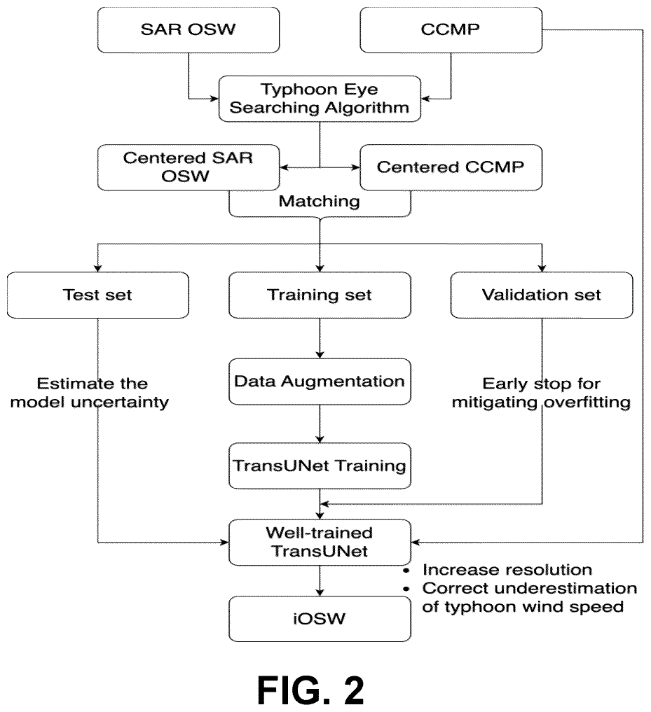

As shown in FIG. 2, the present disclosure provides a training method and an inference method for an OSW downscaling model. As shown in FIG. 2, for training an OSW downscaling model, the training method comprises obtaining a set of wind data samples, wherein the set of wind data samples include a first set of wind data and a second set of wind data, constructing the OSW downscaling model based on TransUNet architecture, inputting the first set of wind data and the second set of wind data into the OSW downscaling model, outputting a set of resulting wind data, adjusting the OSW downscaling model by using a loss function so as to obtain a well-trained OSW downscaling model. For implementing an OSW downscaling model, the inference method comprises, obtaining an input image with a set of wind data, using the well-trained OSW downscaling model to generate an output image with a set of resulting wind data according to the input image.

The training method for the OSW downscaling model according to one embodiment of the present disclosure is shown in FIG. 2, the OSW downscaling model is trained by optimizing model parameters of the OSW downscaling model in a sense of minimizing a loss function. As shown in FIG. 2, the plurality of sets of training samples comprises a first set of wind data samples and a second set of wind data samples, the first set of wind data samples is a set of SAR OSW data, and the second set of wind data samples is a set of CCMP OSW data. The set of SAR OSW data and the set of CCMP OSW data are input to the Typhoon Eye Searching Algorithm to find the center of the set of data. The centered SAR OSW data and centered CCMP OSW data can be obtained from the set of SAR OSW data and the set of CCMP OSW data respectively, wherein centered SAR OSW and centered CCMP are called as typhoon eyes, and typhoon eyes in both the set of SAR OSW data and the set of CCMP OSW data are centered within their image frame. When determining the typhoon eye, if one pixel of a wind image in the set of SAR OSW data is less than a first threshold and if a predefined proportion of the surrounding pixels surpass a second threshold, the one pixel is determined to be the typhoon eye in the set of SAR OSW data of wind image; if one pixel of a wind image in the set of CCMP OSW data is less than a first threshold and if a predefined proportion of the surrounding pixels surpass a second threshold, the one pixel is determined to be the typhoon eye in the set of CCMP OSW data of wind image.

Then centered SAR OSW data and centered CCMP OSW data are matched or paired according to the corresponding typhoon eye, so as to obtain a plurality of sets of matched wind data samples. Then the plurality of sets of matched wind data samples are separated into three sets of data, including test set of data, training set of data and validation set of data. The training set of data is configured for updating the model parameters by minimizing a loss function, the validation set of data is configured for mitigating overfitting, and the test set of data is configured to estimate the final uncertainty of the OSW downscaling model.

Regarding the training set of data, the data in the training set are enriched through data augmentation, and then are input to the TransUNet architecture for training. Meanwhile, the test set and the validation set are also sent to the TransUNet architecture for training, so as to obtain a well-trained TransUNet architecture. The well-trained TransUNet architecture can increase resolution and correct underestimation of typhoon wind speed, and can be used to construct integrated OSW downscaling model. In certain embodiments, all ReLU activation functions in the TransUNet architecture are replaced by leaky ReLU activation functions in the OSW downscaling model. Although the original version of TransUNet uses ReLU as activation function, in certain embodiment of the present application, ReLU activation function is replaced with the leaky ReLU activation function, since the U-wind and V-wind, which may have negative value and are described as follows, are used in the OSW downscaling model in certain embodiments.

The present disclosure further provides an OSW downscaling model trained by the above method and an OSW downscaling method.

The sample set includes OSW data. OSW data can be obtained from the National Oceanic and Atmospheric Administration (NOAA) that cover typhoons for several years, such as from 2015 to 2024, containing OSW data from Sentinel-1, RADARSAT, and RADATSAT-2 satellites. Alternatively, data from ASCAT, Sentinel-1, CYGNSS, and RADARSAT-2 covering several years or from any other sources can be used. The OSW data is obtained from multi sources, including ASCAT, Sentinel-1, CYGNSS, RADARSAT-2, COWVR, and PIESAT SAR. For example, 1075 SAR-derived OSW data covering most typhoons worldwide can be used as a set of SAR OSW data. Further, data from a set of CCMP OSW data can be used. The set of CCMP OSW data combines satellite wind retrievals, in situ wind measurements, and a background wind field from numerical weather analysis to provide a gap-free global wind vector over oceans. CCMP uses a variational approach to ensure data-rich regions and the background wind field are closely collocated in time and space.

In certain embodiments, a typhoon eye search algorithm as described below has provided. The typhoon eye search algorithm comprises the following steps. First, computing two crucial thresholds: Threshold 1, representing the 50th percentile of wind speed, and Threshold 2, denoting the 90th percentile of wind speed. Then scanning all pixels with speeds below Threshold 1. Each pixel contains wind speed at its position in OSW data, wherein scanning means setting a FOR loop to go through all the pixels with speed below Threshold 1. For each such pixel, assessing whether 50% of pixels exhibit speeds surpassing the above Threshold 2 within a given window size. The window sizes used in certain embodiments range from 3×3 to 11×11 with a step of 2 pixels. If such pixel meets the criteria under any of the window sizes, such a pixel is determined as the typhoon eye.

Subsequently, applying the above typhoon eye search algorithm on both the SAR OSW data and its corresponding CCMP OSW data to pinpoint eyes in both CCMP OSW data and SAR OSW data. After the typhoon eye is identified, the typhoon eye in the CCMP wind data is centered within a 40×40 matrix and the typhoon eye in the SAR wind data is centered within a 160×160 matrix. The above alignment process ensures that the typhoon eyes the CCMP wind data and SAR data in both sets of data are centrally positioned in the matrixes. The above typhoon eye search process helps reconcile the discrepancies caused by the time lag between CCMP wind data and SAR wind data.

The typhoon eye search algorithm can effectively locate the center of a typhoon. In order to guarantee perfect results, a manual verification can be conducted, considering some SAR observations only cover a portion of the typhoon without including the center. Specifically, after applying the typhoon eye search algorithm, a manual verification is conducted and any data where the typhoon eye search algorithm did not accurately identify the typhoon center is discarded. After applying the typhoon eye search algorithm and manual verification, optionally the CCMP wind data may be further upsampled to be 160×160 matrixes as the input using bilinear interpolation. The CCMP wind data can be upsampled before applying them to the OSW downscaling mode to facilitate the calculation of the loss function later.

In the inference method for downscaling an OSW according to certain embodiments, the method comprises obtaining an input image with a set of wind data. The wind data in the set of wind data are input into the well-trained OSW downscaling model constructed based on TransUNet architecture. In the wind data, Horizontal wind speed can be represented by two wind components (U-wind and V-wind) contained in SAR OSW data and CCMP OSW data or by total wind speed and wind direction. In such embodiments, the image bands can be composed with the first band designated as U-wind, the second band as V-wind, and the third band as total wind speed. Wind direction is excluded from the bands due to its periodic nature, which poses significant challenges for deep learning algorithms. Instead, in certain embodiments of the present disclosure, the wind direction can be derived from U-wind and V-wind. Setting the third band as total wind speed, along with U-wind and V-wind, aims to enhance the algorithm's ability to learn absolute wind speeds.

In certain embodiments, after separating the plurality of sets of matched wind data samples, the training set of data can be enriched through data augmentation using two main strategies. First, the typhoon center can be positioned in various locations within the images. For CCMP OSW data, the x and y coordinates of the typhoon center in the image frame can be adjusted from the 1^{st} to 20^{th} pixels, or 1^{st} to 40^{th} pixels, or 1^{st} to 60^{th} pixels, with a step of certain pixels, such as 3 pixels, 5 pixels, 7 pixels, 9 pixels. For SAR OSW data, the typhoon center's coordinates in the image are configured to be aligned according to the corresponding CCMP OSW data. The x and y coordinates of the SAR OSW typhoon center are scaled to be several times, such as three times, four times, five times, of those of the CCMP typhoon center. Second, the images of the training set of data can be rotated by 90°, 180°, and 270°. This rotation is applied only to the data where the typhoon is centered in the images. In certain embodiments, as a result of these augmentations, the size of the set of wind data for training can be increased, e.g., increased by a factor of 75, 85, 95 or 100.

For the deep learning architecture and training process, TransUNet architecture is applied as the OSW downscaling model. TransUNet architecture has been recited in Chen, J., Lu, Y., Yu, Q., Luo, X., Adeli, E., Wang, Y., . . . & Zhou, Y. (2021). Transunet: Transformers make strong encoders for medical image segmentation. arXiv preprint arXiv: 2102.04306. TransUNet architecture can effectively capture both global context and large-scale latent information while also enabling precise capture of detailed local features. The goal is to produce wind field outputs with enhanced spatial resolution and corrected wind speeds for typhoons, which differs from segmentation tasks that typically yield class probabilities.

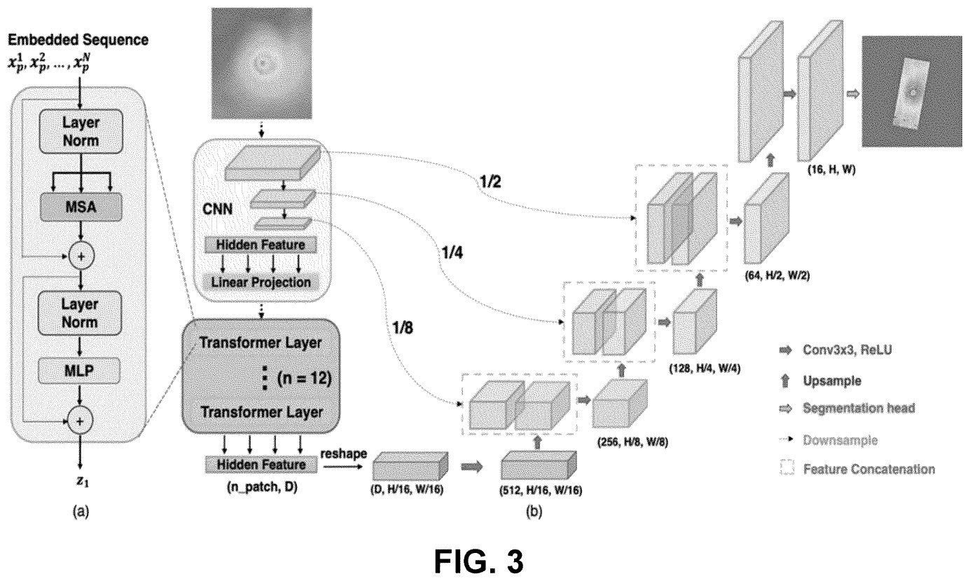

TransUNet architecture comprises an encoder for encoding (downsampling) and a decoder for decoding (upsampling). TransUNet architecture is shown in FIG. 3.

TransUNet architecture is constructed by adding transformer layers on the basis of Unet, including encoder and decoder parts, the encoder part comprises Transformer encoder and a convolutional attention mechanism module, the Transformer encoder is configured to use CNN-transformer algorithm to extract the features of the input image into feature maps and position information, the decoder part comprises multiple convolutional layers and one or more upsampling layers for convolving and upsampling the feature maps and position information from the encoder part.

In the encoding process, a CNN can be used as a feature extractor to generate feature maps for the input. Then for each level of the feature extractor, the output feature maps are then concatenated to the decoder path at the same level. The feature maps are then labeled (vectorized) as a linear projection of a 2D embedding of shape. The embedding is pre-trained and will preserve the position information of the feature maps. Finally, in preparation for the upsampling path, the output is reshaped. A Unet architecture is used to combine the CNN feature maps from the encoder to the globe contextual features encoded by transformer by skip-connection.

In the decoding process, the input from the CNN-Transformer encoder is upsampled by a 3×3 convolutional layer with leaky ReLU activation and is sent to the third-level CNN feature extractor to obtain a resulting feature map. The resulting feature map is then run through a 3×3 convolution layer with leaky ReLU activation again and the output is then sent to the second-level CNN feature extractor. The steps are repeated, and the output is a mask of shape (C, H, W), where C=3, H=image height, and W=image width. C=3 as the image band contains U-Wind, V-Wind, and total wind speed.

The use of leaky ReLU activation allows for the generation of negative values in the U-wind and V-wind outputs.

The SAR wind data serves as the ground truth. However, it only covers a portion of the input image frame. To incorporate constraints beyond the SAR data coverage area, the upsampled CCMP wind data is utilized for loss function calculations outside of the SAR data coverage area but with a smaller weight.

To compute the loss function, firstly applying a mask to the output to calculate the MSE value between the SAR wind and the output in the regions where SAR wind data is present. As SAR OSW only covers a portion of the input image frame, the mask is configured to be derived from SAR OSW, and the output is obtained from TransUNet. Next, applying another mask to both the upsampled CCMP input and the output to compute the MSE value in regions lacking SAR wind data. Finally, combining the two MSE values to define the loss function for training the TransUNet architecture. The loss function is expressed as follows:

$$Loss = \frac{1}{{n}_{1}} \times {\sum }_{i}^{N} {( {W}_{SAR}^{i} - {W}_{DL}^{i} )}^{2} \times {mask}^{i} + \frac{1}{{n}_{2}} \times {\sum }_{i}^{N} ( {W}_{CCMP}^{i} - {W}_{DL}^{i} ) \times ( 1 - {mask}^{i} ) \times 0.1 \qquad ( 1 )$$

where n₁ is the number of pixels that have SAR wind, n₂ is the number of pixels that do not have SAR wind, N is the total number of pixels in the image frame, i represents the i^{th} pixel, W_{SAR}ⁱ is the i^{th} SAR wind data, W_{CCMP}ⁱ is i^{th} CCMP wind data, W_{DL}ⁱ is the i^{th} resulting wind data obtained from the TransUNet architecture, maskⁱ is one if the SAR wind data is available at the i^{th} pixel; otherwise, it is zero.

For both training loss and validation loss, the same loss function can be used. In the test set of data, the root mean square deviation (RMSD) is only quantified over regions where the SAR wind is available, so as to quantify the test error. The RMSD is defined using the following equation:

$$R M S D = \sqrt{\frac{1}{{n}_{1}} \times {\sum }_{i}^{N} {( {W}_{SAR}^{i} - {W}_{DL}^{i} )}^{2} \times {mask}^{i}} \qquad ( 2 )$$

where n₁ is the number of pixels that have SAR wind, W_{SAR}ⁱ is the i^{th} SAR wind data, W_{CCMP}ⁱ is i^{th} CCMP wind data, W_{DL}ⁱ is the i^{th} resulting wind data obtained from the TransUNet architecture, maskⁱ is one if the SAR wind data is available at the i^{th} pixel; otherwise, it is zero.

During network training, the validation loss is calculated with the validation set of data after each epoch and the checkpoint is saved only if the validation loss has decreased. Training will be halted if the validation loss does not improve for the predetermined consecutive epochs, such as 15, 20, 25, 30 consecutive epochs, to prevent overfitting.

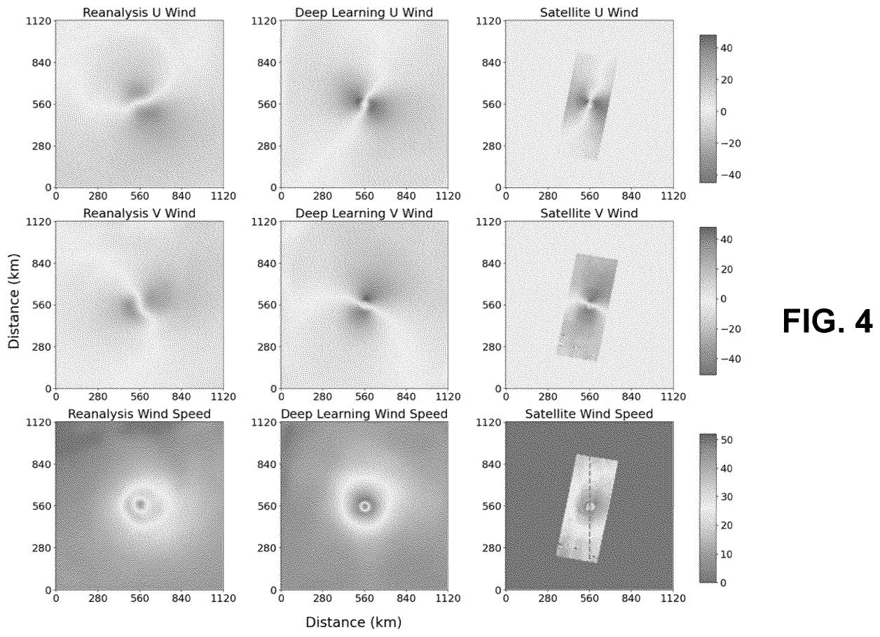

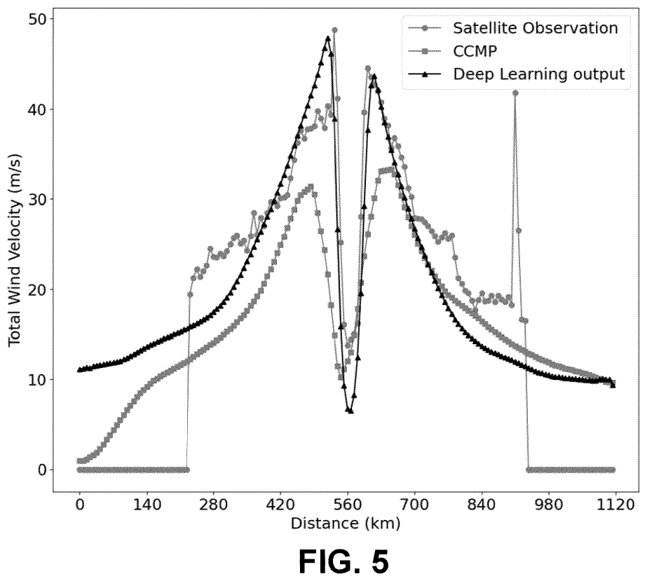

The OSW downscaling model obtained in the embodiments of the present disclosure have a promising match with the SAR observations over regions where SAR wind is available. As shown in FIG. 4, the top two rows show the two horizontal wind speed (U wind and V wind referring to wind speed in two directions), and the bottom row shows the total wind speed. On average in the test set, the RMSD between CCMP and SAR is 11.43 m/s, while the RMSE can be decreased to 5.13 m/s based on the method the present application which utilizes the deep learning algorithm. Beyond SAR coverage, the simulations show reasonable match with the CCMP input, as shown in FIG. 5. Overall, the present disclosure can successfully improve the spatial resolution of CCMP and correct its underestimation over typhoons. Moreover, the OSW downscaling model of the embodiment of the present disclosure can provide a complete SAR-like wind field without any data gap.

The main advantages of this invention with respect to the prior art can be described from the following three aspects.

First, it features high accuracy and high resolution. Compared with the existing products, the integrated OSW products of the present application have a better performance under the high-speed wind condition with 1-km resolution at a near real-time (NRT) latency.

Second, it involves the physical atmospheric model for accurate weather forecasts. Taking advantage of the accurate integrated OSW data, the accuracy of the weather nowcasts and forecasts can be improved. The improvement of the weather forecast accuracy is 20% or even greater compared with the current operational forecast system.

The present disclosure also provides a computer system, comprising a memory, a processor and a computer program stored on the memory, the processor executes the computer program to implement a training method for an OSW downscaling model as described herein.

The computer system can be a server or a terminal. The server can be an independent physical server or a terminal. It can be a server cluster or distributed system composed of multiple physical servers, or it can provide cloud services, cloud databases, cloud computing, cloud functions, cloud storage, network services, cloud communications, middleware services, domain name services, security services, CDN, and cloud servers for basic cloud computing services such as big data and artificial intelligence platforms. The terminal can be a smartphone, tablet, laptop, desktop computer, smart wearable device, etc., but is not limited to this. The terminal and the server can be connected directly or indirectly through wired or wireless communication methods, which is not limited in this disclosure. Those skilled in the art can understand that the above-mentioned computer system structure does not limit the computer system, and may include more or less components, or combine certain components, or arrange different components. The computer system may also include a display unit, etc., which will not be described in detail here. Specifically, in this embodiment, the processor in the computer system will load the executable files corresponding to the processes of one or more disclosure programs into the memory according to the instructions, and the processor will run the executable files stored in the memory so as to implement various functions.

The present disclosure also provides a computer program product that is configured to implement a training method for an OSW downscaling model as described herein.

The embodiments or elements showcased within this disclosure, including the specific illustrations and materials utilized in examples, are intended to be illustrative, not restrictive. They allow for a wide range of alterations, adjustments, or adaptations that align with the fundamental concept of the present disclosure. It's important to clarify that all depicted diagrams are solely for illustrative purposes; they are neither to scale nor are they precise reproductions of actual devices.

Wherever not already described explicitly, individual embodiments, or their individual aspects and features, described in relation to the drawings can be combined or exchanged with one another without limiting or widening the scope of the described disclosure, whenever such a combination or exchange is meaningful and in the sense of this disclosure. Advantages which are described with respect to a particular embodiment of present disclosure or with respect to a particular figure are, wherever applicable, also advantages of other embodiments of the present disclosure.

### CITED REFERENCES

Cui, Z., Pu, Z., Tallapragada, V., Atlas, R., & Ruf, C. S. (2019). A Preliminary Impact Study of CYGNSS Ocean Surface Wind Speeds on Numerical Simulations of Hurricanes. Geophysical Research Letters, 46 (5), 2984-2992. https://doi.org/10.1029/2019GL082236
Duan, B., Zhang, W., Yang, X., Dai, H., & Yu, Y. (2017). Assimilation of Typhoon Wind Field Retrieved from Scatterometer and SAR Based on the Huber Norm Quality Control. Remote Sensing, 9 (10), 987. https://doi.org/10.3390/rs9100987
Guo, C., Ai, W., Hu, S., Du, X., & Chen, N. (2022). Sea Surface Wind Direction Retrieval Based on Convolution Neural Network and Wavelet Analysis. IEEE Journal of Selected Topics in Applied Earth Observations and Remote Sensing, 15, 3868-3876. https://doi.org/10.1109/JSTARS.2022.3173001
Li, J., Hong, D., Gao, L., Yao, J., Zheng, K., Zhang, B., & Chanussot, J. (2022). Deep learning in multimodal remote sensing data fusion: A comprehensive review. International Journal of Applied Earth Observation and Geoinformation, 112, 102926. https://doi.org/10.1016/j.jag.2022.102926
Mao, H., Kathuria, D., Duffield, N., & Mohanty, B. P. (2019). Gap Filling of High-Resolution Soil Moisture for SMAP/Sentinel-1: A Two-Layer Machine Learning-Based Framework. Water Resources Research, 55(8), 6986-7009. https://doi.org/10.1029/2019WR024902
Munir, A., Blasch, E., Kwon, J., Kong, J., & Aved, A. (2021). Artificial Intelligence and Data Fusion at the Edge. IEEE Aerospace and Electronic Systems Magazine, 36(7), 62-78. https://doi.org/10.1109/MAES.2020.3043072
Pu, Z., Wang, Y., Li, X., Ruf, C., Bi, L., & Mehra, A. (2022). Impacts of Assimilating CYGNSS Satellite Ocean-Surface Wind on Prediction of Landfalling Hurricanes with the HWRF Model. Remote Sensing, 14(9), 2118. https://doi.org/10.3390/rs14092118
Wang, M., Wang, D., Xiang, Y., Liang, Y., Xia, R., Yang, J., et al. (2023). Fusion of ocean data from multiple sources using deep learning: Utilizing sea temperature as an example. Frontiers in Marine Science, 10. Retrieved from https://www.frontiersin.org/articles/10.3389/fmars.2023.1112065
Wang, Y., Shi, X., Lei, L., & Fung, J. C.-H. (2022). Deep Learning Augmented Data Assimilation: Reconstructing Missing Information with Convolutional Autoencoders. Monthly Weather Review, 150 (8), 1977-1991. https://doi.org/10.1175/MWR-D-21-0288.1
Zanchetta, A., & Zecchetto, S. (2021). Wind direction retrieval from Sentinel-1 SAR images using ResNet. Remote Sensing of Environment, 253, 112178. https://doi.org/10.1016/j.rse.2020.112178
Zecchetto, S., De Biasio, F., Valle, A. della, Quattrocchi, G., Cadau, E., & Cucco, A. (2016). Wind Fields From C-and X-Band SAR Images at VV Polarization in Coastal Area (Gulf of Oristano, Italy). IEEE Journal of Selected Topics in Applied Earth Observations and Remote Sensing, 9(6), 2643-2650. https://doi.org/10.1109/JSTARS.2016.2538322
Zhou, L., Zheng, G., Li, X., Yang, J., Ren, L., Chen, P., et al. (2017). An Improved Local Gradient Method for Sea Surface Wind Direction Retrieval from SAR Imagery. Remote Sensing, 9(7), 671. https://doi.org/10.3390/rs9070671

Atlas, R., R. N. Hoffman, J. Ardizzone, S. M. Leidner, J. C. Jusem, D. K. Smith, D. Gombos, 2011: A cross-calibrated, multiplatform ocean surface wind velocity product for meteorological and oceanographic applications. Bull. Amer. Meteor. Soc., 92, 157-174. https://doi.org/10.1175/2010BAMS2946.1
Mears, C. A., Scott, J., Wentz, F. J., Ricciardulli, L., Leidner, S. M., Hoffman, R., & Atlas, R. (2019). A near-real-time version of the cross-calibrated multiplatform (CCMP) ocean surface wind velocity data set. Journal of Geophysical Research: Oceans, 124(10), 6997-7010.
Chen, J., Lu, Y., Yu, Q., Luo, X., Adeli, E., Wang, Y., . . . & Zhou, Y. (2021). Transunet: Transformers make strong encoders for medical image segmentation. arXiv preprint arXiv: 2102.04306.
Vaswani, A., Shazeer, N., Parmar, N., Uszkoreit, J., Jones, L., Gomez, A. N., . . . & Polosukhin, I. (2017). Attention is all you need. Advances in neural information processing systems, 30.
Ronneberger, O., Fischer, P., & Brox, T. (2015). U-net: Convolutional networks for biomedical image segmentation. In Medical image computing and computer-assisted intervention-MICCAI 2015: 18th international conference, Munich, Germany, Oct. 5-9, 2015, proceedings, part III 18 (pp. 234-241). Springer International Publishing.

What is claimed is:

1. A computer-implemented method for downscaling an ocean surface wind (OSW) comprising:
obtaining an input image of a set of wind data,
constructing an ocean surface wind downscaling model based on a TransUNet architecture,
using the ocean surface wind downscaling model to generate an output image of a set of resulting wind data with increased resolution according to the input image, and
before the ocean surface wind downscaling model is used to generate the output image, training the ocean surface wind downscaling model according to a plurality of sets of training samples, wherein the ocean surface wind downscaling model is trained by optimizing model parameters of the ocean surface wind downscaling model in a sense of minimizing a loss function.

2. The computer-implemented method according to claim 1, wherein the plurality of sets of training samples comprise a first set of wind data samples and a second set of wind data samples, the first set of wind data samples is a set of synthetic aperture radar (SAR) ocean surface wind data, and the second set of wind data samples is a set of Cross-Calibrated Multi-Platform (CCMP) ocean surface wind data.

3. The computer-implemented method according to claim 2, wherein typhoon eyes in both the first set and the second set of wind data samples are centered within their image frame respectively, so as to train the ocean surface wind downscaling model and reconcile discrepancies caused by time lag between the first set and the second set of wind data samples.

4. The computer-implemented method according to claim 3, wherein if one pixel of a wind image in the first set of wind data samples is less than a first threshold and if a predefined proportion of the surrounding pixels surpass a second threshold, the one pixel is determined to be the typhoon eye in the wind image of the first set of wind data samples.

5. The computer-implemented method according to claim 4, wherein if one pixel of a wind image in the second set of wind data samples is less than a first threshold, and if a predefined proportion of the surrounding pixels surpass a second threshold, the one pixel is determined to be the typhoon eye in the wind image of the second set of wind data samples.

6. The computer-implemented method according to claim 5, wherein the training of the ocean surface wind downscaling model comprises pairing the wind images of the first set of wind data samples with the wind images of the second set of wind data samples based on the date, when the wind images of the first set of wind data samples and the wind images of the second set of wind data samples are obtained.

7. The computer-implemented method according to claim 6, wherein all data of the paired wind images of the first set of wind data samples and the paired wind images of the second set of wind data samples are separated into training set of data, validation set of data, and test set of data, wherein the training set of data is configured for updating the model parameters of the ocean surface wind downscaling model in a sense of minimizing a loss function.

8. The computer-implemented method according to claim 7, wherein the validation set of data is configured for mitigating overfitting, and the test set of data is configured to estimate the final uncertainty of the ocean surface wind downscaling model.

9. The computer-implemented method according to claim 7, wherein the first set of wind data samples and the second set of wind data samples in the training set of data are respectively enriched through data augmentation before being input into the ocean surface wind downscaling model.

10. The computer-implemented method according to claim 9, wherein the second set of wind data samples have been further upsampled using bilinear interpolation before being input into the ocean surface wind downscaling model.

11. The computer-implemented method according to claim 10, wherein all ReLU activation functions were replaced by leaky ReLU activation functions in the ocean surface wind prediction model.

12. The computer-implemented method according to claim 1, wherein the loss function is determined by applying a first mask to the resulting wind data samples obtained by using the ocean surface wind downscaling model to calculate a first mean squared error (MSE) value between the first set of wind data samples in the training set of data and resulting wind data in the regions where wind data in the first set of wind data samples is present, applying a second mask to both the resulting wind data samples obtained by using the ocean surface wind downscaling model and the second set of wind data samples to calculate a second MSE value between the second set of wind data samples in the training set of data and the resulting wind data samples obtained by using the ocean surface wind downscaling model in regions where the first set of wind data samples is lacking, and combining the first MSE values and the second MSE values.

13. The computer-implemented method according to claim 12, wherein the loss function used for training is expressed as follows:
$$Loss = \frac{1}{{n}_{1}} \times {\sum }_{i}^{N} {( {W}_{SAR}^{i} - {W}_{DL}^{i} )}^{2} \times {mask}^{i} + \frac{1}{{n}_{2}} \times {\sum }_{i}^{N} ( {W}_{CCMP}^{i} - {W}_{DL}^{i} ) \times ( 1 - {mask}^{i} ) \times 0.1$$
where n₁ is the number of pixels that have SAR wind, n₂ is the number of pixels that do not have SAR wind, N is the total number of pixels in the image frame, i represents i^{th} pixel, W_{SAR}ⁱ is i^{th} SAR wind data, W_{CCMP}ⁱ is i^{th} CCMP wind data, W_{DL}ⁱ is i^{th} resulting wind data obtained from the TransUNet architecture, maskⁱ is one if the SAR wind data is available at the i^{th} pixel;
otherwise, maskⁱ is zero.

14. The computer-implemented method according to claim 12, wherein the step of training the ocean surface wind downscaling model is halted when a validation loss obtained from the loss function does not improve for predetermined consecutive epochs.
